(19) United States
(12) Patent Application Publication
(10) Pub. No.: US 2010/0035380 A1
(43) Pub. Date: Feb. 11, 2010

(54) Method for fabricating package structure of stacked chips

(75) Inventors: Chun-Wei Li, Chu-Nan (TW); Ming-Hai Tsai, Chu-Nan (TW); Chi-Yun Tuan, Chu-Nan (TW); Sheng-Hui Chien, Chu-Nan (TW); Chung-Chiao Pai, Chu-Nan (TW); Yu-Wen Liu, Chu-Nan (TW)

Correspondence Address: BACON & THOMAS, PLLC, 625 SLATERS LANE, FOURTH FLOOR, ALEXANDRIA, VA, 22314-1176, US

(73) Assignee: Kun Yuan Technology Co., Ltd., Chu-Nan (TW)

(21) Appl. No.: 12/289,991

(22) Filed: Nov. 10, 2008

(30) Foreign Application Priority Data
Aug. 5, 2008 (TW) 097129637

(51) Int. Cl. H01L 21/50

(52) U.S. Cl. 438/107; 257/E21.499

(57) ABSTRACT

The invention relates to a method for fabricating a package structure of stacked chips, comprising the following steps: firstly, providing a substrate; attaching a first chip and a second chip on the upper surface of the substrate, in which the second chip is stacked on the upper side of the first chip; then connecting a first bonding wire between a second solder pad of the second chip and a first region of a first solder pad of the first chip; and connecting a second bonding wire between a second region of the first solder pad of the first chip and the metal contact of the substrate, whereby the invention is capable of tremendously reducing the volume as a whole, effectively solving the problem of having much bonding wire circuit, and reducing the volume and quantity occupied by the solder pads on the substrate, thereby reducing complexity of the circuit layout on the substrate.

### BACKGROUND OF THE INVENTION

1. Field of the Invention

The invention relates to a method for fabricating a package structure of stacked chips, particularly to an arrangement of bonding wires in packaging process of semiconductor chips.

2. Background of the Invention

Due to that electronic products are developed to become lighter, thinner, shorter and smaller, package structures for protecting semiconductor chips and providing connection of external circuits also need to be lighter, thinner, shorter and smaller. A commonly seen conventional multi-chip package structure is arranged side by side, which is to mount more than two chips on the surface of a substrate side by side. However, a side by side structure will cause enlargement of the substrate size due to increase of the quantity of chips, easily resulting in a huge volume of the semiconductor device so as not to meet the requirement of the consumers.

Further, accompanied by progress of the techniques, a upper-down stacking way of multiple chips is developed. Please refer to FIG. 1. Such an approach solves the problem of huge size of the semiconductor device through arranging the two-dimensional circuit layout side by side so as to effectively reduce the whole size tremendously. However, accompanied by multi-layered stacking, the bonding wire circuit is getting more complicated, rendering short circuit resulting from easy generation of interleaving of bonding wires during bonding process, such that it is not easy to increase the space of chip stacking. In addition, as the quantity of stacking chips is increasing, the size occupied by the metal contacts of the substrate is getting bigger, easily resulting in limitation for designing and in increase of complexity of the circuit layout of the substrate.

Furthermore, to overcome the above-mentioned problem of complication of the bonding wire circuit in stacking chips, as shown in FIG. 2, a conventional technique is developed to a serial connection of stacking of solder points, in which two solder pads respectively located on two stacked chips and having the same function are electrically connected and stacked to a solder pad of the same chip using a ball soldering tool. Such an approach is capable of solving the problem of complication of the bonding wire circuit. However, more accompanied problems are derived. The process is in general as follows, firstly respectively attaching an upper chip 81 and a lower chip 82 on a substrate 85, in which the bonding procedure of an upper bonding wire 83 is bonding from the upper chip 81 to the lower chip 82 and the bonding procedure of a lower bonding wire 84 is bonding from stacking in series the upper bonding wire 83 at the same bonding point of the lower chip 82 to the substrate 85.

Based on it, the defects of the conventional technique are as follows.

(1) The chip aluminum pad is easily damaged due to repetitively exerting pressure to the same point. When proceeding with bonding of the bonding wire 84, a second time operating pressure has to be exerted repetitively at the second bonding point of the bonding wire 83. That is, as the same point on the aluminum pad 821 of the lower chip 82 is subject to the operating pressure of the solder needle in the second time, the aluminum pad of the chip is easily subject to damage, resulting in open circuit of the chip circuit.

(2) In addition, please refer to FIG. 3. Similarly, when stacking in series the bonding wires to proceed with bonding of the bonding wire 84, it is easy to generate deviation resulting from tolerance caused by the machine or control problem, such that it is unable to proceed with bonding and soldering by completely aiming at the same center point. Additionally, since the upper surface of the original bonding point is not flat, as the solder needle 86 exerts the operating pressure in the second time, the operating center point of the operating pressure is shifted. Further, since the combination strength of a gold ball and an aluminum pad is far lower than that of a gold ball and a gold ball, as the aluminum pad 821 of the lower chip is subject to the operating pressure of the solder needle 86 in the second time in deviation and in tilt, it is easy to cause stripping of the first layered gold ball 831 and the aluminum pad 821 of the lower chip due to poorer combination strength of the two metals, thereby stripping them to generate an open circuit.

(3) Further, it is not easy to control the wiring curvature when stacking in series the second layer. Please refer again to FIG. 3. When stacking in series the bonding wire 84 on the second layer, it is unable to proceed with bonding operation at the predetermined center position, quite often due to convexity of the gold ball 831 on the first layer and the tolerance of the machine equipment, such that the point of the force exerted by the solder needle 86 at the solder wire on the second layer is unstable, resulting in that the wiring curvature of the bonding wire 84 is not easily controlled and it is unable to proceed with the bonding operation according to the predetermined route of the bonding wire. Therefore, it incurs unstable situation, and seriously even causes banding together and an open circuit of the bonding wire.

It can be known that it is an urgent need in the industry as to how to obtain a structure of stacking chips, which is capable of tremendously reducing the whole volume, easily controlling the wiring curvature of the bonding wire, reducing complexity of the wiring layout of the substrate, avoiding easy damage to the chip(s) and aluminum pad, and efficiently solving the problem of complication of the circuit of bonding wires.

### BRIEF SUMMARY OF THE INVENTION

The invention relates to a method for fabricating a package structure of stacked chips, comprising the following steps: (A) providing a substrate, on an upper surface thereof being established with at least a metal contact; (B) attaching a first chip and a second chip on the upper surface of the substrate without covering the at least a metal contact, in which the upper surface of the first chip is set up with at least a first solder pad and the at least a first solder pad includes a first region and a second region, which regions are adjacent each other, and in which the second chip is stacked on the upper side of the first chip without covering the at least a solder pad and the upper surface of the second chip is set up with at least a second solder pad; and (C) connecting a first bonding wire between the at least a second solder pad of the second chip and the first region of the at least a first solder pad of the first chip, and connecting a second bonding wire between the second region of the at least a first solder pad of the first chip and the at least a metal contact of the substrate. Therefore, the invention is capable of tremendously reducing the volume as a whole, effectively solving the problem of having much bonding wire circuit, and reducing the quantity of the solder pads on the substrate, thereby reducing complexity of the circuit layout on the substrate.

Preferably, in step (B) of the invention, at least a lower-layered chip is further attached between the substrate and the first chip without covering the at least a metal contact, and the upper surface of the at least a lower-layered chip is set up with at least a lower-layered solder pad without being covered by the first chip. In addition, in step (B), at least a sandwich chip is further attached between the first chip and the second chip without covering the at least a first solder pad. The upper surface of the at least a sandwich chip is set up with a sandwich solder pad which is not covered by the second chip. Further, in step (B), at least an upper-layered chip is further attached on the upper side of the second chip without covering the at least a second solder pad, and the upper surface of the at least an upper-layered chip is set up with at least an upper-layered solder pad.

Furthermore, in step (C) of the invention, a first bonding point of the first bonding wire is electrically connected to the second solder pad of the second chip, and a second bonding point of the first bonding wire is electrically connected to the first region of the first solder pad. That is, it may proceed with the bonding procedure of the first bonding wire from the second solder pad on the upper second chip to the first region of the first solder pad on the lower first chip.

Moreover, in step (C) of the invention, a first bonding point of the first bonding wire may also be electrically connected to the first region of the first solder pad, and a second bonding point of the first bonding wire may be electrically connected to the second solder pad of the second chip. That is, it may proceed with the bonding procedure of the first bonding wire from the first region of the first solder pad on the lower first chip to the second solder pad on the upper second chip.

Further, in step (C) of the invention, a first bonding point of the second bonding wire may be electrically connected to the second region of the first solder pad, and a second bonding point of the second bonding wire may be electrically connected to the metal contact of the substrate. That is, it may proceed with the bonding procedure of the second bonding wire from the second region of the first solder pad on the upper first chip to the metal contact of the lower substrate.

Still further, in step (C) of the invention, a first bonding point of the second bonding wire may be electrically connected to the metal contact of the substrate, and a second bonding point of the second bonding wire may be electrically connected to the second region of the first solder pad. That is, it may proceed with the bonding procedure of the second bonding wire from the metal contact of the lower substrate to the second region of the first solder pad on the upper first chip.

Among which, the invention may further comprise a step (D) after step (C), i.e. packaging and enclosing the first chip, the second chip, the first bonding wire, the second bonding wire and at least a part of the substrate into a packing plastic body. Besides, the first solder pad and the second solder pad are respectively an aluminum pad.

### BRIEF DESCRIPTION OF THE DRAWINGS

FIG. 1 is a schematic diagram of a conventional structure for stacking chips.

FIG. 2 is a schematic diagram showing stacking solder points in series connection for stacking chips conventionally.

FIG. 3 is a schematic diagram showing contact of a solder needle during stacking solder points in series connection conventionally.

FIG. 4 is a schematic diagram of a first preferred embodiment of the invention.

FIG. 5 is a schematic diagram showing a first solder pad of the first preferred embodiment of the invention.

FIG. 6 is a flow chart of the first preferred embodiment of the invention.

FIG. 7 is a flow chart showing step (B) of the first preferred embodiment of the invention.

FIG. 8 is a schematic diagram of a second preferred embodiment of the invention.

FIG. 9 is a flow chart showing step (B) of the second preferred embodiment of the invention.

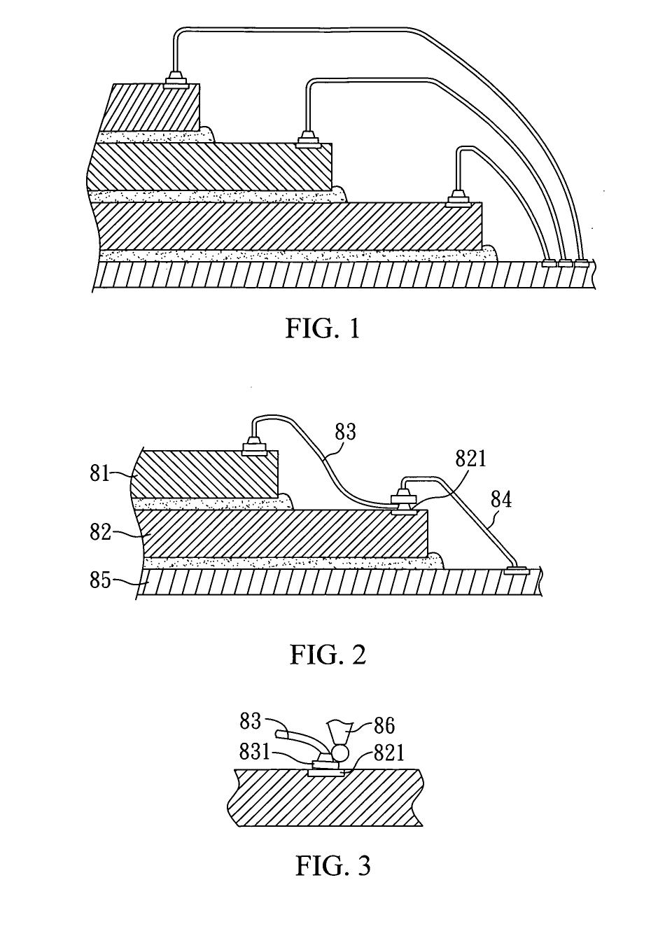

### DETAILED DESCRIPTION OF THE INVENTION

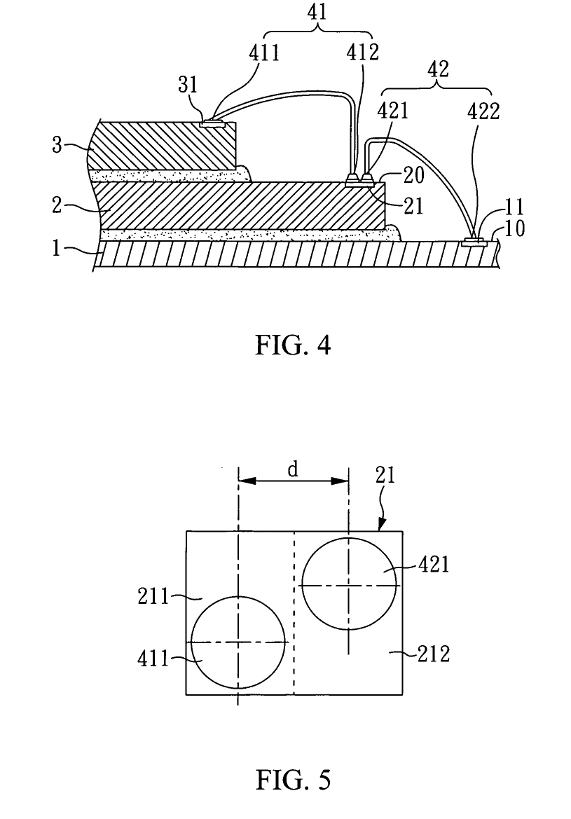

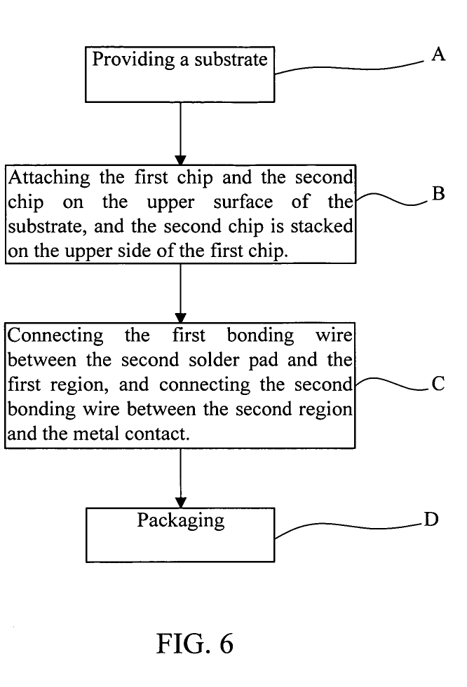

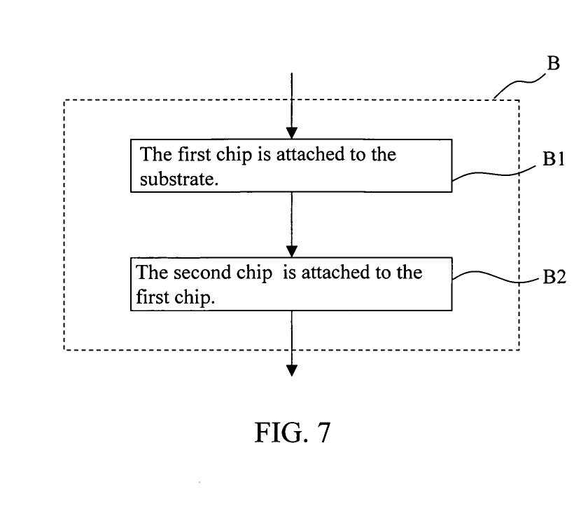

Please refer to FIG. 4 together with FIG. 6. FIG. 4 is a schematic diagram showing a method for fabricating a package structure of stacked chips of a first preferred embodiment of the invention. FIG. 6 is a flow chart of the first preferred embodiment of the invention. The invention is adapted for use in a stacking package structure of any IC chips, such as a memory card IC. The embodiment is interpreted using an SD memory card, while not limited to it. The invention comprises the following steps: firstly, providing a substrate 1, on an upper surface 10 thereof being established with a metal contact 11 (the so-called golden finger); then attaching a first chip 2 and a second chip 3 on the upper surface of the substrate 1 without covering the metal contact 11, in which the attaching material used is thermosetting epoxy material in general. In the embodiment, the first chip 2 is first attached to the upper side of the substrate 1 and then the second chip 3 is attached to the upper side of the first chip 2. The steps may be found in the flow chart of FIG. 7.

Inside it, an upper surface 20 of the first chip 2 is set up with a first solder pad 21, which is an aluminum pad. The first solder pad 21 includes a first region 211 and a second region 212, which regions are adjacent each other and electrically connected, as also shown in FIG. 5. FIG. 5 is a schematic diagram showing the first solder pad of the first preferred embodiment of the invention, in which the second chip 3 is stacked on the upper side of the second chip 2 without covering the first solder pad 21 and the upper surface of the second chip 3 is also provided with a second solder pad 31, which is also an aluminum pad.

Then, a first bonding wire 41 (the so-called “golden wire bonding”) is connected between the second solder pad 31 of the second chip 3 and the first region 211 of the first solder pad 21 of the first chip 2. In the embodiment, a first bonding point 411 (1st bond, also called “ball bond”) of the first bonding wire 41 is electrically connected to the first region 211 of the first solder pad 21 and a second soldering point 412 (2nd bond, also called “switch bond”) of the first bonding wire 41 is electrically connected to the second solder pad 31 of the second chip 3. That is, it may proceed with the bonding procedure of the first bonding wire 41 from the first region 211 of the first solder pad 21 on the lower first chip 2 to the second solder pad 31 on the upper second chip 3. However, the bonding procedure of the first bonding wire 41 is not limited to this. It may also proceed with the bonding procedure from the second solder pad 31 on the upper second chip 3 to the first region 211 of the first solder pad 21 on the lower first chip 2.

In addition, a second bonding wire 42 is connected between the second region 212 of the first solder pad 21 of the first chip 2 and the metal contact 11 of the substrate 1. In this embodiment, a first bonding point 421 of the second bonding wire 42 is electrically connected to the second region 212 of the first solder pad 21 and a second soldering point 422 of the second bonding wire 42 is electrically connected to the metal contact 11 of the substrate 1. That is, it may proceed with the bonding procedure of the second bonding wire 42 from the second region 212 of the first solder pad 21 on the upper first chip 2 to the metal contact 11 of the lower substrate 1. However, the bonding procedure of the second bonding wire 42 is not limited to this. It may also proceed from the metal contact 11 of the lower substrate 1 to the second region 212 of the first solder pad 21 on the upper first chip 2.

Please refer to FIG. 5. As shown in the figure, the first solder pad 21 includes the above-mentioned first region 211 and second region 212. It is provided on the first region 211 the first bonding point 411 of the first bonding wire 41, it is provided on the second region 212 the first bonding point 421 of the second bonding wire 42, and the center point respectively of the first bonding points 411, 421 of the two bonding wires is spaced apart from a center point distance d. The center point distance d is for absorbing production tolerance and allowance of a machine or allowance resulting from control so as to avoid overlapping of two solder points. Based on this, the invention is capable of completely overcoming the conventional problem of solder points stacked in series and will not easily cause damage of the solder pad due to repetitively applying pressure to the same point. Further, the invention will not cause stripping or short circuit of the solder pad and the solder point resulting from applying deviated and tilted working pressure due to tolerance and deviation of the solder needle. In addition, since the substrate is connected in the flat solder pad and thus it can fully proceed with the bonding operation along a pre-determined route due to stability of the curvature of the solder wires.

However, the proceeding sequence of the first bonding wire 41 and the second bonding wire 42 is not limited to it. The wiring operation may be done by first bonding the second bonding wire 42 and then bonding the first bonding wire 41. Further, a packaging step is taken lastly, i.e. packaging and enclosing the first chip 2, the second chip 3, the first bonding wire 41, the second bonding wire 42 and at least a part of the substrate 1 into a packaging plastic body. Still further, the bonding wire adopted in the embodiment is golden wire and the diameter of the golden wire may be 0.7 (18 um), 0.8 (20 um) or 0.9 mil (23 um). Of course, accompanied by progress of the process equipments, the diameter of the golden wire is getting smaller, while the thinner golden wire can be adaptively used in the invention completely.

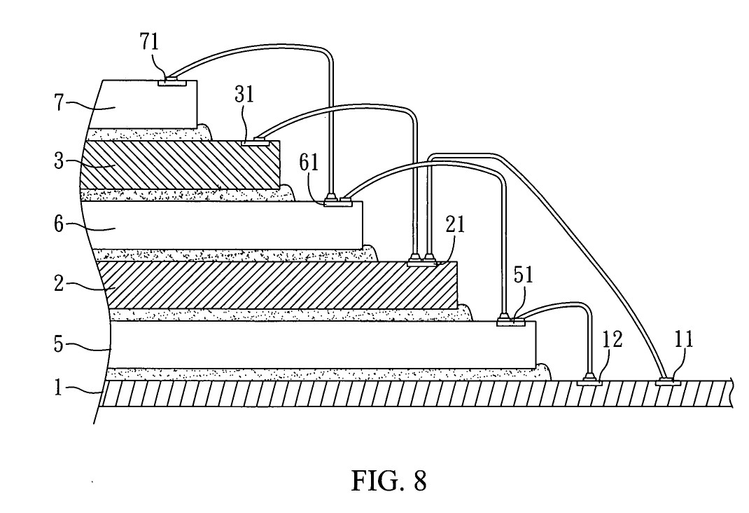

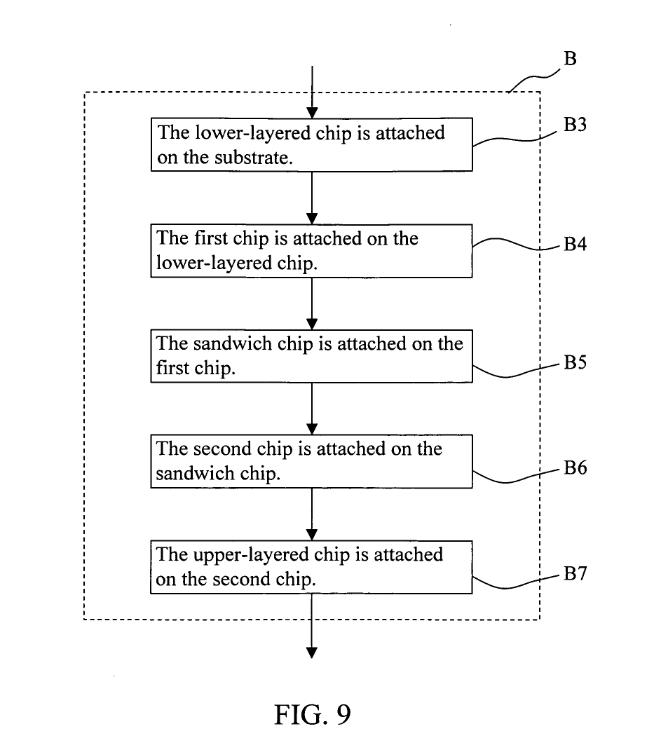

Please refer to FIG. 8 together with FIG. 9. FIG. 8 is a schematic diagram of a second preferred embodiment of the invention. FIG. 9 is a flow chart showing step (B) of the second preferred embodiment of the invention. The difference between the second preferred embodiment and the first preferred embodiment lies that in the second preferred embodiment, a lower-layered chip 5, a sandwich chip 6 and an upper-layered chip 7 are further provided to interpret that invention is adapted to be used in a structure of stacking IC chips having different functions, in which the lower-layered chip 5 is attached between the substrate 1 and the first chip 2 without covering metal contacts 11, 12, the sandwich chip 6 is attached between the first chip 2 and the second chip 3 without covering the first solder pad 21, and the upper-layered chip 7 is attached to the upper side of the second chip 3 without covering the second solder pad 31.

The stacking procedure is shown in FIG. 9. Firstly, the lower-layered chip 5 is attached on the substrate 1. Then the first chip 2 is attached on the lower-layered chip 5, in which the upper surface of the lower-layered chip 5 is provided with a lower-layered solder pad 51 without being covered by the first chip 2. Then the sandwich chip 6 is attached on the first chip 2, and the upper surface of the sandwich chip 6 is provided with at least a sandwich solder pad 61. And then, the second chip 3 is attached on the sandwich chip 6, while the at least a sandwich solder pad 61 is not covered by the second chip 3. Lastly, the upper-layered chip 7 is attached to the upper side of the second chip 3 and the upper surface of the upper-layered chip 7 is provided with at least an upper-layered solder pad 71.

In addition, the arrangement of the bonding wires in the second preferred embodiment is as follows. The lower-layered chip 5, the sandwich chip 6 and the upper-layered chip 7 are respectively electrically connected using the method of the invention, and the lower-layered chip 5 is connected to the metal contact 12. The original first chip 2 and second chip 3 are stacked as mentioned in the above embodiment and connected to the metal contact 11 of the substrate 1. The second preferred embodiment is mainly to interpret that the structure of stacking IC chips may be used to stack chips with different functions. The way of stacking chips is not merely to stack the chips one by one. Chips with the same function are needed to be connected individually may also adopt the method of the invention. Therefore, the invention may be adapted for use in any kind of structures for stacking chips.

The above embodiments are exampled to interpret the invention for the sake of convenience. What is claimed by the invention should be based on the description of the claims, but not limited to the above embodiments.

What is claimed is:

1. A method for fabricating a package structure of stacked chips, comprising the following steps:
(A) providing a substrate, on an upper surface thereof being established with at least a metal contact;
(B) attaching a first chip and a second chip on the upper surface of the substrate without covering the at least a metal contact, in which the upper surface of the first chip is set up with at least a first solder pad and the at least a first solder pad includes a first region and a second region, which regions are adjacent each other, and in which the second chip is stacked on the upper side of the first chip without covering the at least a first solder pad and the upper surface of the second chip is set up with at least a second solder pad; and
(C) connecting a first bonding wire between the at least a second solder pad of the second chip and the first region of the at least a first solder pad of the first chip, and connecting a second bonding wire between the second region of the at least a first solder pad of the first chip and the at least a metal contact of the substrate.

2. A method for fabricating a package structure of stacked chips as claimed in claim 1, wherein in step (B), at least a lower-layered chip is further attached between the substrate and the first chip without covering the at least a metal contact.

3. A method for fabricating a package structure of stacked chips as claimed in claim 1, wherein in step (B), at least a sandwich chip is further attached between the first chip and the second chip without covering the at least a first solder pad.

4. A method for fabricating a package structure of stacked chips as claimed in claim 1, wherein in step (B), at least an upper-layered chip is further attached to the upper side of the second chip without covering the at least a second solder pad.

5. A method for fabricating a package structure of stacked chips as claimed in claim 1, wherein in step (C), a first bonding point of the first bonding wire is electrically connected to the second solder pad of the second chip, and a second bonding point of the first bonding wire is electrically connected to the first region of the first solder pad.

6. A method for fabricating a package structure of stacked chips as claimed in claim 1, wherein in step (C), a first bonding point of the first bonding wire is electrically connected to the first region of the first solder pad, and a second bonding point of the first bonding wire is electrically connected to the second solder pad of the second chip.

7. A method for fabricating a package structure of stacked chips as claimed in claim 1, wherein in step (C), a first bonding point of the second bonding wire is electrically connected to the second region of the first solder pad, and a second bonding point of the second bonding wire is electrically connected to the metal contact of the substrate.

8. A method for fabricating a package structure of stacked chips as claimed in claim 1, wherein in step (C), a first bonding point of the second bonding wire is electrically connected to the metal contact of the substrate, and a second bonding point of the second bonding wire is electrically connected to the second region of the first solder pad.

9. A method for fabricating a package structure of stacked chips as claimed in claim 1, further comprising a step after step (C):
(D) packaging and enclosing the first chip, the second chip, the first bonding wire, the second bonding wire and at least a part of the substrate into a packing plastic body.

10. A method for fabricating a package structure of stacked chips as claimed in claim 1, wherein the first solder pad and the second solder pad are respectively an aluminum pad.
